(19) United States
(12) Patent Application Publication
(10) Pub. No.: US 2023/0155079 A1
(43) Pub. Date: May 18, 2023

(54) LIGHT EMITTING DEVICES INCLUDING A COLOR CONVERSION MATERIAL AND LIGHT EXTRACTING STRUCTURES AND METHOD OF MAKING THEREOF

(71) Applicant: NANOSYS, INC., Milpitas, CA (US)

(72) Inventors: Brian KIM, Santa Clara, CA (US); Homer ANTONIADIS, Mountain View, CA (US)

(21) Appl. No.: 17/980,683

(22) Filed: Nov. 4, 2022

Related U.S. Application Data
(60) Provisional application No. 63/278,571, filed on Nov. 12, 2021.

(51) Int. Cl. H01L 33/50

(52) U.S. Cl. CPC H01L 33/507; H01L 33/502

(57) ABSTRACT

A light emitting device includes a light emitting diode configured to emit blue or ultraviolet radiation incident photons, a color conversion material located over the light emitting diode and configured to absorb the incident photons emitted by the light emitting diode and to generate converted photons having a longer peak wavelength than a peak wavelength of the incident photons, and at least one light extracting feature located between the light emitting diode and the color conversion material.

### FIELD

This disclosure relates to light emitting devices, and particularly to light emitting diodes formed in optical cavities with a color conversion material and light extracting structures and methods of fabricating the same.

### BACKGROUND

Light emitting devices are used in electronic displays, such as backlights in liquid crystal displays in laptops and televisions. Light emitting devices include light emitting diodes (LEDs) and various other types of electronic devices configured to emit light.

For light emitting devices, such as light emitting diodes (LEDs), the emission wavelength is determined by the band gap of the active region of the LED together with size dependent quantum confinement effects. Often the active region includes one or more bulk semiconductor layers or quantum wells (QW). For III-nitride based LED devices, such as GaN based devices, the active region (e.g., bulk semiconductor layer or QW well layer) material may be ternary, having a composition such as InₓGa₁₋ₓN, where 0<x<1.

The band gap of such III-nitride materials is dependent on the amount of In incorporated in the active region. Higher indium incorporation yields a smaller band gap and thus longer wavelength of the emitted light. As used herein, the term “wavelength” refers to the peak emission wavelength of the LED. It should be understood that a typical emission spectra of a semiconductor LED is a narrow band of wavelength centered around the peak wavelength.

### SUMMARY

An embodiment light emitting device includes a light emitting diode configured to emit blue or ultraviolet radiation incident photons, a color conversion material located over the light emitting diode and configured to absorb the incident photons emitted by the light emitting diode and to generate converted photons having a longer peak wavelength than a peak wavelength of the incident photons, and at least one light extracting feature located between the light emitting diode and the color conversion material.

An further embodiment light emitting device includes an optical cavity bounded by a cavity wall, a light emitting diode located in the optical cavity and configured to emit blue or ultraviolet radiation incident photons, a color conversion material located over the light emitting diode and configured to absorb the incident photons emitted by the light emitting diode and to generate converted photons having a longer peak wavelength than a peak wavelength of the incident photons, a reflective material located over the cavity wall, and a transparent material located over the metallic material.

### BRIEF DESCRIPTION OF THE DRAWINGS

FIG. 1A is a vertical cross-sectional view of an intermediate structure that may be used in the formation of an array of light emitting devices, according to various embodiments.

FIG. 1B is a vertical cross-sectional view of a further intermediate structure that may be used in the formation of an array of light emitting devices, according to various embodiments.

FIG. 1C is a vertical cross-sectional view of a further intermediate structure that may be used in the formation of an array of light emitting devices, according to various embodiments.

FIG. 1D is a vertical cross-sectional view of an array of light emitting devices, according to various embodiments.

FIG. 1E is a vertical cross-sectional view of a further array of light emitting devices, according to various embodiments.

FIG. 2A is a top perspective view of a first patterned matrix having a plurality of vias formed therein, according to various embodiments.

FIG. 2B is a top perspective view of a second patterned matrix having a plurality of vias formed therein, according to various embodiments.

FIG. 3 is a vertical cross-sectional view of a micro-LED that emits a Lambertian radiation pattern, according to various embodiments.

FIG. 4 is a vertical cross-sectional view of a comparative array of light emitting devices, according to a comparative embodiment.

FIG. 5 is a vertical cross-sectional view of a further array of light emitting devices including a light extracting material layer, according to various embodiments.

FIG. 6A is a vertical cross-sectional view of a further array of light emitting devices including a light extracting material layer and light extracting features, according to various embodiments.

FIG. 6B is a vertical cross-sectional view of a further array of light emitting devices including a light extracting material layer and light extracting features, according to various embodiments.

FIG. 6C is a vertical cross-sectional view of a further array of light emitting devices including a light extracting material layer and light extracting features, according to various embodiments.

FIG. 7A is a vertical cross-sectional view of an array of light emitting devices in which each pixel has been divided into a plurality of sub-cells, according to various embodiments.

FIG. 7B is a vertical cross-sectional view of a further array of light emitting devices in which each pixel has been divided into a plurality of sub-cells, according to various embodiments.

FIG. 7C is a top view of an array of light emitting devices in which each pixel has been divided into a plurality of sub-cells, according to various embodiments.

FIGS. 8 and 10 are vertical cross-sectional views of further arrays of light emitting devices in which cavity walls may be configured to include reflecting materials, according to various embodiments.

FIG. 9A is a vertical cross-sectional view of reflection pattern of photons hitting a reflecting cavity wall having a metallic reflector, according to various embodiments.

FIG. 9B is a vertical cross-sectional view of reflection pattern of photons hitting a reflecting cavity wall having a transparent material formed over a metal reflector, according to various embodiments.

### DETAILED DESCRIPTION

A display device, such as a direct view display may be formed from an ordered array of pixels. Each pixel may include a set of subpixels that emit light at a respective peak wavelength. For example, a pixel may include a red subpixel, a green subpixel, and a blue subpixel. Each subpixel may include one or more light emitting diodes that emit light of a particular wavelength. A traditional arrangement is to have red, green, and blue (RGB) subpixels within each pixel. Each pixel may be driven by a backplane circuit such that any combination of colors within a color gamut may be shown on the display for each pixel. The display panel may be formed by a process in which LED subpixels are soldered to, or otherwise electrically attached to, a bond pad located on a backplane. The bond pad may be electrically driven by the backplane circuit and other driving electronics.

Various embodiments provide a light emitting device configured to create high efficiency red, green, blue, and/or other color pixelated light from a shorter wavelength excitation source using photonically pumped quantum dots in a vertical cavity structure. Embodiment micron-scale light emitting diodes (micro-LED) which have a length and width less than 100 microns, such as 5 to 20 microns, may be used in display devices. This emerging technology offers ultimate black levels by using individual LEDs at each pixel location of a display device. Further, each pixel may be configured to generate a single color of light. A backplane upon which individual LEDs may be attached may include a substrate (e.g., plastic, glass, semiconductor, etc.) with thin-film transistor (TFT) structures, silicon CMOS, or other driver circuitry that may be configured to apply a voltage or current to each LED independently. For example, the backplane may include TFTs on a glass or plastic substrate, or bulk silicon transistors (e.g., transistors in a CMOS configuration) on a bulk silicon substrate or on a silicon-on-insulator (SOI) substrate. While micro-LEDs are described in the embodiments below, it should be noted that other types of LEDs (e.g., nanowire or other nanostructure LEDs) or macro-LEDs having a size (e.g., width and length) greater than 100 microns may also be used instead of or in addition to the micro-LEDs.

In some embodiments, a size of each micro-LED may be smaller than a pitch of the pixels used in a particular display device, such as a direct view display device or another display device. For example, a 300 ppi display may have pixels having a pitch of approximately 85 microns, while a typical micro-LED for such a display may have a width that is approximately 20 microns. Micro-LEDs that include an indium-doped GaN material (i.e., LEDs that emit a color that depends on indium doping of GaN) may suffer degradation of efficiency and uniformity with decreasing LED size (e.g., sizes less than 10 microns) due to difficulties associated with indium doping of GaN crystal structures. Thus, longer peak wavelength emitting III-nitride micro-LEDs (e.g., red LEDs) which utilize a higher indium content in their active regions may have insufficient efficiency and uniformity due to the degraded indium doping.

Some embodiments of the instant disclosure may include a photonic emitter based on a LED having an undoped GaN active region (e.g., a micro-LED having a GaN light emitting active layer) or a low indium doped InGaN active region (e.g., a micro-LED having a low indium content InGaN light emitting active layer) coupled with a photonically pumped color conversion material. Such LEDs may be ultraviolet (UV) radiation or blue light emitting micro-LEDs having a peak emission wavelength in the UV radiation or blue light spectral region (e.g., 370 to 460 nm, such as 390 to 420 nm, for example 400 to 410 nm). As used herein, the blue light spectral region includes blue and violet colors as perceived by the human observer.

In one embodiment, the color conversion material may include quantum dots. The quantum dots may be configured to absorb photons generated by the GaN-based LED and to generate various colors of light depending on the properties of the quantum dots (e.g., quantum dot size and material composition). Such structures avoid problems associated with indium doping of small GaN structures. Alternatively, the color conversion material may comprise an inorganic phosphor or an organic dye.

In the size regime (i.e., sizes less than 10 microns) appropriate for augmented reality (AR) displays (e.g., smart glasses) and other applications, the use of a undoped GaN or low indium doped GaN LED active region and photonically pumped quantum dots to create various colors may provide display devices having better uniformity across an array of micro-LEDs. Such arrays may also exhibit higher efficiency than systems having colored LEDs based on relatively high indium doped GaN (e.g., red LEDs containing a higher amount of indium than blue LEDs). The increased efficiency and uniformity may be achieved because quantum dots may be manufactured with a high degree of uniformity of size and material composition. Such uniform quantum dots have corresponding uniform (i.e., narrow linewidth) emission properties.

Extraction of light emitted by micro-LEDs may be increasingly challenging with decreasing pixel pitch and micro-LED size. Disclosed embodiments provide improved optical extraction of photons (e.g., along a specific direction) generated by the quantum dots, while maintaining high efficiency by avoiding loss of photons to absorbing surfaces. Disclosed systems may also prevent or reduce pump photons from escaping the device, thereby ensuring purity of the color emitted by a given micro-LED. This may be accomplished by forming optical cavity walls that are reflective, including a light extracting material layer, and including other light extracting structures, such as micro lenses, a distributed Bragg reflector (DBR), textured or corrugated interfaces, etc., as described in greater detail below.

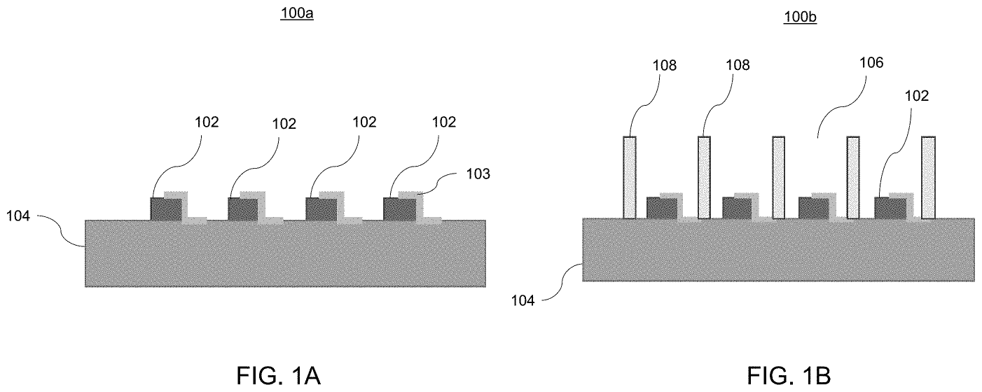

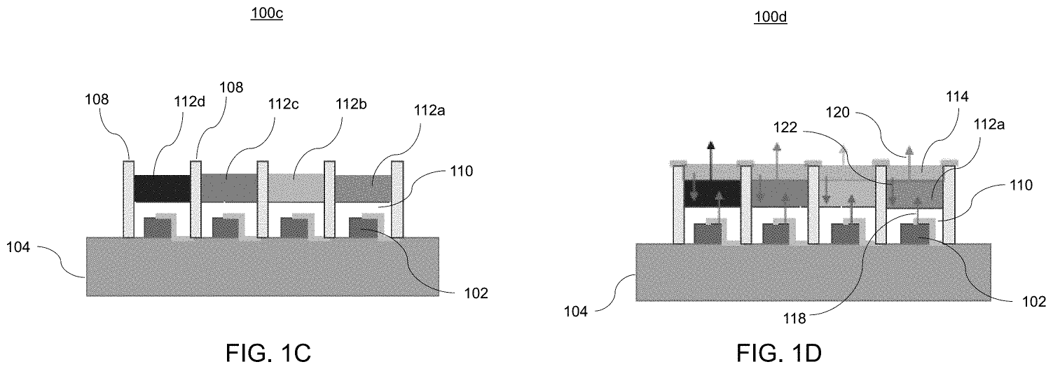

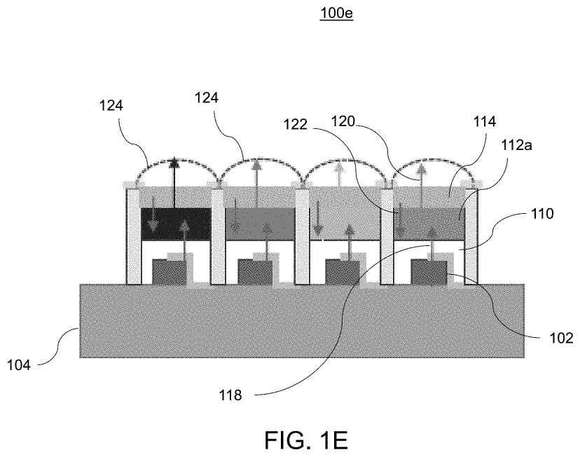

FIG. 1A is a vertical cross-sectional view of an intermediate structure 100a that may be used in the formation of an array of light emitting devices, according to various embodiments. The intermediate structure 100a may include a plurality of micro-LEDs 102 formed on a substrate 104. As described above, the micro-LEDs 102 may include a micro-LEDs which have peak emission wavelength in the UV radiation or blue light spectral region (e.g., UV or blue emitting micro-LEDs, also referred to as UV or blue LEDs). Such LEDs may include undoped GaN active regions that are configured to emit ultraviolet (UV) photons and/or blue spectral range photons.

In one embodiment, the micro-LEDs 102 may have at least one electrode 103 located on the top of the LED and facing away from the substrate 104. The electrode 103 may comprise an anode or a cathode electrode. In one embodiment, the micro-LEDs 102 may comprise vertical LEDs in which the second electrode (not shown for clarity) is located between the substrate 104 and the bottom of the micro-LED 102. In another embodiment, the micro-LEDs may comprise lateral LEDs in which both electrodes are located on the same side of the LED (e.g., on top or on bottom sides of the LED).

The substrate 104 may be a backplane having electrical circuitry (e.g., TFT and/or CMOS circuits) configured to supply voltages and currents to the micro-LEDs 102 via the electrodes (including the electrodes 103) to thereby control light emission by the micro-LEDs 102. A backplane may be an active or passive matrix backplane substrate for driving LEDs. As used herein, a “backplane substrate” refers to any substrate configured to affix multiple devices thereupon. In one embodiment, the backplane may include a substrate including silicon, glass, plastic, and/or at least other material that may provide structural support to devices attached thereto. In one embodiment, the backplane substrate may be a passive backplane substrate, in which metal interconnect structures (not shown) including metallization lines are present, for example, in a crisscross grid and dedicated active devices (e.g., TFTs) for each LED are not present. In another embodiment, the backplane substrate may be an active backplane substrate, which includes metal interconnect structures as a crisscross grid of conductive lines and further includes dedicated active devices (e.g., CMOS transistors or TFTs) for each LED at one or more intersections of the crisscross grid of conductive lines.

FIG. 1B is a vertical cross-sectional view of a further intermediate structure 100b that may be used in the formation of an array of light emitting devices, according to various embodiments. Intermediate structure 100b may include a plurality of optical cavities 106 formed over the micro-LEDs 102. Each optical cavity may be bounded by cavity walls 108. The optical cavities 106 may be constructed using a reflective material which has suitable mechanical properties to form high aspect ratio cavities (e.g., 5 microns or less, such as 1-2 microns, in diameter, and 10 microns or more, such as 20-30 microns, in height) with relatively thin cavity walls 108. The cavity walls 108 may have a thickness of less than 10 microns, such as 0.5-5 microns, including 1-2 microns. The cavity walls 108 may form an insulating matrix.

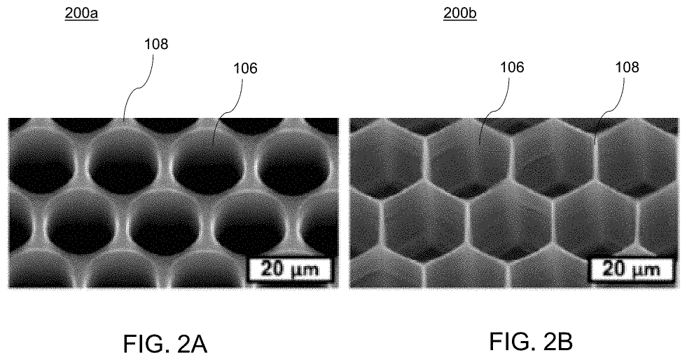

The matrix material may be chosen to be compatible with both thermal evaporative processing steps and solvent based fluidic depositions and evaporation. One such matrix material is alumina, although silica, titania, or other insulating metal oxide materials may be used. Various materials that are typically used to fabricate micro-electromechanical (MEMS) devices may be used to form the optical cavities 106 bounded by cavity walls 108 made of an electrically insulating material (e.g., alumina). Such materials have a relatively high index of refraction and are suitable for forming structures having high aspect ratios. A layer of such matrix material (not shown in FIG. 1B) may be grown or deposited on the micro-LED 102 array located on the substrate 104 and techniques such as etching and other micro machining approaches may be used to generate optical cavities 106 in the material. FIG. 2A is a top perspective view of a matrix 200a having a plurality of cylindrical optical cavities 106 bounded by cavity walls 108. FIG. 2B is a top perspective view of a matrix 200b having a plurality of hexagonal optical cavities 106 bounded by cavity walls 108.

In one embodiment, a voltage may be applied to an anode or cathode electrode 103 of the micro-LEDs 102 to thereby form one side of an etch bias. For example, if the matrix 200a or 200b (i.e., the cavity walls 108) comprise alumina, then the porous alumina may be formed by anodic oxidation. In this embodiment, an aluminum metal layer may be deposited over the micro-LEDs 102, and then electrochemically anodized to form a porous anodic alumina matrix with optical cavities (i.e., pores) 106 bounded by anodic alumina cavity walls 108. The substrate 104 containing the aluminum layer may be placed in an acid electrolyte (e.g., oxalic acid, chromic acid, sulfuric acid and/or phosphoric acid), and a voltage may be applied to the electrodes 103 of the micro-LEDs 102 and/or to an external electrode to form the porous anodic alumina matrix containing the optical cavities (i.e., pores) 106 bounded by the alumina cavity walls 108. The optical cavities 106 may be arranged in a hexagonal array in an anodic alumina matrix.

FIG. 1C is a vertical cross-sectional view of a further intermediate structure 100c that may be used in the formation of an array of light emitting devices, according to various embodiments. Intermediate structure 100c may include a light extracting material layer 110 and a color conversion material (112a, 112b, 112c, 112d) formed in the optical cavities 106 over the array of micro-LEDs 102. The light extracting material layer 110 may have an index of refraction that is lower than an index of refraction of the material forming the cavity walls 108. For example, the light extracting material layer 110 may have an index of refraction of less than 1.7, such as 1.3 to 1.5 for alumina cavity walls 108. The lower refractive index of the light extracting material layer 110 may cause pump photons (i.e., photons generated by the micro-LEDs 102) to be reflected from cavity walls 108 rather than being absorbed by or transmitted through that cavity walls 108. Such reflection prevents loss of photons and thereby acts to increase the quantum efficiency of the device.

Various polymer materials may be used as a light extracting material layer 110. One such polymer is Jet-144 (i.e., an inkjet compatible polymer), which has an index of refraction of 1.44 and which may be deposited into the optical cavities 106 using an inkjet system. A thickness of the cavity walls 108 may be configured to be as thick as possible to increase a probability that photons that do not reflect from the cavity walls 108 are absorbed (i.e., extinguished) so that they do no penetrate into an adjacent cavity.

The light extracting material layer 110 may be deposited using various techniques including ink jet, vacuum, pressure, and/or gravitational deposition. After deposition, the polymer may be cross-linked, for example, by exposure to ultra-violet (UV) radiation. In other embodiments, a solvent in which the polymer is dissolved may be drawn out by evaporation leaving a residual cross-linked polymer as the light extracting material layer 110 in each cavity. In various embodiments, the light extracting material layer 110 may be formed with various thicknesses and may or may not contain additional light scattering materials, such as ZrO2, TiO₂ or SiO₂ nano or micro beads, textured or corrugated interface, etc., as described in greater detail below. The light extracting material layer 110 may partially fill the optical cavities 106 such that empty cavity space may remain over the top of the light extracting material layer 110 in each cavity.

The color conversion material (112a, 112b, 112c, 112d) may then be formed in the optical cavities 106 (e.g., see FIG. 1B) over the light extracting material layer 110 (e.g., see FIG. 1C). The color conversion material (112a, 112b, 112c, 112d) may include quantum dots corresponding to various different colors. In this example, the color conversion material (112a, 112b, 112c, 112d) may include a plurality of first quantum dots 112a, a plurality of second quantum dots 112b, a plurality of third quantum dots 112c, and a plurality of fourth quantum dots 112d, which are configured to convert UV pump photons into photons having first, second, third, and fourth colors, respectively. The second and third colors may comprise different peak wavelengths in the green color spectrum range. Alternatively, only three quantum dot colors may be used.

The quantum dots may each be formed as a nanocrystal having a 1 to 10 nm diameter, such as 2 to 8 nm nanocrystals of a compound semiconductor material, such as a Group III-V semiconductor material (e.g., indium phosphide, as described in U.S. Pat. No. 9,884,763 B1, incorporated herein by reference in its entirety), a Group II-VI semiconductor material (e.g., ZnSe, ZnS, ZnTe, CdS, CdSe, etc., core-shell quantum dots, as described in U.S. Patent Application Publication US 2017/0250322 A1, incorporated herein by reference in its entirety), and/or Group I-III-VI semiconductor material (e.g., AgInGaS/AgGaS core-shell quantum dots, as described in U.S. Pat. No. 10,927,294 B2, incorporated herein by reference in its entirety). The quantum dots may emit different color light (e.g., reg, green or blue) depending on their diameter. The larger dots emit longer wavelength light while the smaller dots emit shorter wavelength light. The quantum dots may be suspended in a material (e.g., a polymer such as polyimide) having a different (e.g., higher) index of refraction from that of the light extracting material layer 110. For example, the polyimide material may be a refractive index of 1.6 to 1.75, such as about 1.7.

Quantum dots corresponding to various colors may be selectively deposited in respective cavities. For example, first cavities may be formed by etching first vias in a matrix material. First quantum dots corresponding to first color may then be introduced into the first cavities and a layer of protective material may then be formed over the first quantum dots. The process may then be repeated to form second cavities, third cavities, etc., and to respectively introduce second quantum dots, third quantum dots, etc. into the respective cavities.

In other embodiments, a photoresist may be deposited over all cavities except a plurality of first cavities. A first layer of quantum dots configured to generate a first color (e.g., red) may then be deposed into the plurality of first cavities corresponding to subpixels having the first color. A polymer in which the first quantum dots are suspended may then be cross linked by evaporation or by exposure to UV light. The process may then be repeated for the other optical cavities to respectively deposit quantum dots configured to generate other color light (e.g., green and blue).

Alternatively, the color conversion material (112a, 112b, 112c, 112d) may comprise an inorganic phosphor or an organic dye. An optional organic planarization layer may be formed over the color conversion material. The color conversion material and the optional organic planarization layer may partially fill the optical cavities 106.

FIG. 1D is a vertical cross-sectional view of an array 100d of light emitting devices, according to various embodiments. As shown, the array 100d may include a color selector 114 formed in and/or over the optical cavities 106. The color selector 114 may include a color filter array and/or a distributed Bragg reflector. In one embodiment, the color selector 114 may be formed in the optical cavities and may extend to the top of the cavity walls 108 such that the optical cavities 106 are completely filled with the above materials.

The color conversion material (112a, 112b, 112c, 112d) may be configured to absorb the pump photons 118 and to convert them to emitted converted photons (e.g., visible light, such as red, green or blue light) 120. In some embodiments, the color conversion material (112a, 112b, 112c, 112d) may not be sufficiently thick and/or dense to fully convert all pump photons 118 into converted photons 120. Thus, the color selector 114 formed over the color conversion material (112a, 112b, 112c, 112d) absorbs and/or reflects all or a portion of the pump photons 118 that are not converted by the color conversion material (112a, 112b, 112c, 112d), without absorbing and/or reflecting the converted photon 120 emitted by the color conversion material.

Each of the micro-LEDs 102 may be configured to emit pump photons 118 having a common wavelength or within a range of the target wavelengths. For example, GaN-based micro-LEDs 102 may emit pump photons 118 having a wavelength that is 400 to 410 nm, such as approximately 405 nm (i.e., in the blue or near-UV part of the electromagnetic spectrum). The micro-LEDs 102 may exhibit a high degree of uniformity and may exhibit high efficiency. However, slight variations in the wavelength of such micro-LEDs 102 may not be easily visible to the eye. Further, any leakage of pump photons 118 through the color conversion material (112a, 112b, 112c, 112d) may cause minimal degradation of the color purity of converted photons 120.

In one embodiment, the color selector 114 includes a color filter array may include an organic dye embedded in an organic polymer. The dye may be configured to absorb UV radiation of the pump photons 118 but to not absorb blue, green, or red light of the converted photons. Optionally, a different dye may be applied over each of the colored subpixels (e.g., red, green, and blue subpixels). For example, a first dye filter material configured to primarily transmit red light may be applied to red subpixels, a second dye filter material configured to primarily transmit green light may be applied to green subpixels, and third dye filter material configured to primarily transmit blue light may be applied to blue subpixels. The color filters may by formed using a further photolithographic process. In various embodiments, a thin film encapsulation (TFE) layer or layer stack may then be applied over the color filter materials to provide protection against air or moisture ingress into the quantum dot layers of the color conversion material. In one embodiment, the TFE may comprise a tri-layer stack of two silicon nitride layers separated by a polymer layer.

In an alternative embodiment, the color selector 114 may include a DBR formed over the color conversion material (112a, 112b, 112c, 112d). The DBR may be configured to reflect pump photons 118, which are transmitted through the color conversion material, back into the optical cavity 106 as reflected photons 122 (e.g., UV or deep blue photons) and to allow the converted photons 120 to be transmitted out of the optical cavity 106. The DBR may be formed as an alternating multi-layer stack of materials (not shown) having different indices of refraction. For example, the DBR may be formed as a stack of N layers alternating between TiO₂ (n=2.5) and SiO₂ (n=1.5) with N being 2 or more. In other embodiments, various other materials having respective indices of refraction may be used in constructing the DBR.

Embodiments in which the DBR includes TiO₂ and SiO₂ with N=2 may have a bandwidth of 164 nm at a center wavelength of 405 nm and a maximum reflectivity R of 84%. Embodiments in which the DBR stack includes a larger number of layers (i.e., N>2) may have increased reflectivity. As such, the probability of a UV pump photon 118 passing through the DBR may be decreased. The UV photons 122 reflected from the DBR back into the optical cavity 106 may circulate through the color conversion material (112a, 112b, 112c, 112d) and may thereby have an increased probability of also being converted to converted photons 120 having the target wavelength (e.g., green, blue, or red). In this way, any UV reflected photons 122 that are not initially absorbed by the color conversion material (112a, 112b, 112c, 112d) may eventually be absorbed and converted to converted photons 120 having the target emission wavelength. This process, which is sometimes called “photon recycling” may increase the quantum efficiency of the device.

If the micro-LEDs 102 comprise shorter wavelength blue light emitting LEDs, then the DRB 114 may block the shorter wavelength blue light (i.e., pump photons 118) of the micro-LEDs 102 but transmit the longer wavelength converted photons 120 emitted from blue quantum dots of the color conversion material. Alternatively, the DBR 114 may be omitted over the blue light emitting subpixels.

The DBR may be formed by a deposition (e.g., by evaporation) of a multi-layer stack (not shown) over all of the subpixels. As such, the DBR may provide additional protection against moisture and oxygen ingress into the quantum dot layer. A higher value of N may further increase both the DBR reflectivity and the protection from moisture and oxygen, leading to improved overall system performance and durability.

In various additional embodiments, other materials may be used for the various components of the device. For example, the DBR may include a wide range of materials each having respective refractive indices, for example, nitrides (TiN, AN, TiN, etc.), polysilicon, etc. Some embodiments may include multiple layers of quantum dots, multiple DBR structures, etc. The light extracting material layer 110, described above, may be omitted in some embodiments or multiple light extraction material layers 110 may be used. By using a more effective DBR 114, the layer thickness and density of the color conversion material (112a, 112b, 112c, 112d) may be reduced. In further embodiments, the optical cavities 106 may be formed in various ways. For example, the optical cavities 106 may be formed in a separate matrix layer which may then be attached to the array of micro-LEDs 102 after the optical cavities 106 are formed. Further embodiments may also include light-collimating elements to mitigate performance degradation that may otherwise occur due to lateral photon propagation.

FIG. 1E is a vertical cross-sectional view of a further array 100e of light emitting devices, according to various embodiments. As shown, the array 100e of light emitting devices includes micro lenses 124 formed over optical cavity 106. Each micro lens 124 may help to improve light extraction from each micro-LED structure and may thereby improve efficiency of the array 100e. In general, extraction of light emitted by micro-LEDs may be increasingly challenging with decreasing pixel pitch and micro-LED size. In this regard, the color conversion material (112a, 112b, 112c, 112d) may be chosen to be sufficiently thick to convert all of the pump photons 118 into converted photons 120, each having a specific color. The thickness of the color conversion material (112a, 112b, 112c, 112d) may be very large compared to a lateral dimension of the subpixel. In such a structure, photons may move diffusively rather than ballistically out of the micro-LED subpixel. Such diffusively moving photons may spread to adjacent subpixels, potentially causing optical cross talk.

Disclosed embodiments provide improved optical extraction of photons (e.g., along a specific direction) generated by the quantum dots, while maintaining high efficiency by avoiding loss of photons to absorbing surfaces. As described above, this may be accomplished by forming a matrix structure that include cavity walls 108 that are reflective, including a light extracting material layer 110, and/or including a color selector 114, such as a DBR.

The use of quantum dots as a color conversion material (112a, 112b, 112c, 112d) for micro-LED displays may include deposition and patterning of dense quantum dot layers at very small feature sizes. To achieve sufficient absorption of pump photons 118 (e.g., see FIGS. 1D and 1E) in the quantum dot layer, subpixels with aspect ratios of greater than 1:1 may be used. Such subpixels may also be separated by cavity walls 108 formed of an opaque matrix material to prevent color crosstalk (i.e., photons from one micro-LED propagating into neighboring subpixels) in the display.

Various embodiments include a matrix, such as a matrix 200a or 200b (e.g., see FIGS. 2A and 2B), which may allow better light extraction from each subpixel and may mitigate photonic color crosstalk. Using the matrix as a template and sequentially opening vias corresponding to different color subpixels allows the deposition and curing of quantum dot inks without relying on a high-resolution photo-patternable resin formulation. Other embodiments may use other techniques to fabricate LED structures.

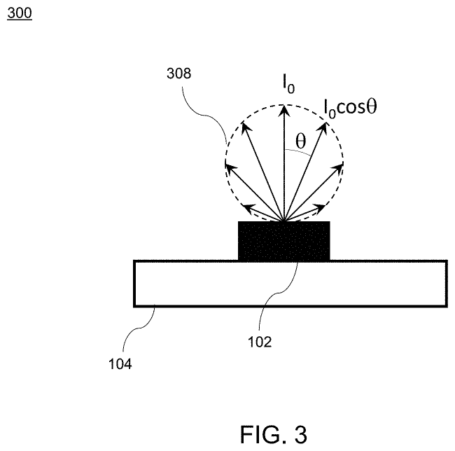

FIG. 3 is a vertical cross-sectional view of an intermediate structure 300 illustrating a radiation pattern of a micro-LED 102 formed on a substrate 104, according to various embodiments. The micro-LED 102 may be configured to emit a Lambertian radiation pattern. In this regard, the intensity (i.e., number of photons per unit time per unit area) of radiation emitted varies as the cosine of the emission angle relative to the direction perpendicular to an emitting surface. The various arrows in FIG. 3 each have a length that is proportional to the intensity of emitted radiation in the direction of the arrow. For example, radiation emitted at an angle θ may have an intensity given by I=I₀ cos (θ), where I is the intensity that is emitted perpendicular to the surface. The circle 308 shows the continuous angular cosine dependence of the emitted radiation from the top surface of the micro-LED 102. As shown, the emitted intensity is greatest in the direction perpendicular to the top surface and decreases away from the direction perpendicular to the surface, and is zero parallel to the surface (i.e., zero emission from the top surface parallel to the top surface).

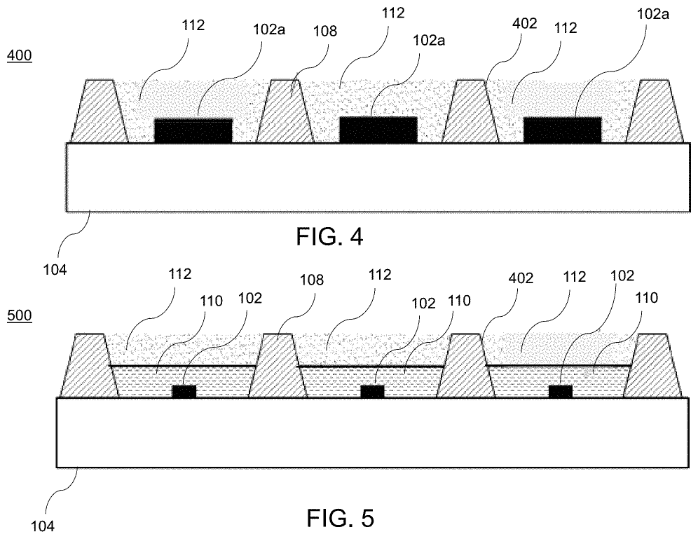

FIG. 4 is a vertical cross-sectional view of a comparative array 400 of light emitting devices, according to a comparative embodiment. The array 400 of light emitting devices may include a plurality of LEDs 102a that are formed within a plurality of cavities that are bounded by cavity walls 108. The LEDs 102a may be coupled to a substrate (e.g., backplane) 104, which may include electrical circuitry that is configured to control the LEDs 102. Each cavity may include a color conversion material 112.

The array 400 of light emitting devices may be similar to the to the intermediate structure 100c, described above with reference to FIG. 1C. However, in contrast to the intermediate structure 100c, the array 400 of light emitting devices excludes the light extracting material layer 110. In this comparative embodiment, the LEDs 102a may be chosen to have a large top emission surface to enlarge a contact area between the LEDs 102a and color conversion materials. Such a large contact area may improve the coupling between the emitted photons and the color conversion material. However, the larger area of the LEDs 102a increases the subpixel size and increases the device cost.

In embodiments of the present disclosure, smaller micro-LEDs 102 may be used in conjunction with a light extracting material layer 110 and various light extraction features, as described in greater detail with reference to FIGS. 5 to 7C, below. The smaller micro-LEDs 102 decrease the size of each subpixel and reduce cost of the device.

FIG. 5 is a vertical cross-sectional view of an array 500 of light emitting devices including a light extracting material layer 110, according to various embodiments. The array 500 of light emitting devices may include a plurality of micro-LEDs 102 that are formed within a plurality of cavities that are bounded by cavity walls 108. The micro-LEDs 102 may be coupled to a substrate (e.g., backplane) 104, which may include electrical circuitry that is configured to control the micro-LEDs 102. Each cavity may include a color conversion material 112 and a light extracting material layer 110. The cavity walls 108 may include angled surfaces 402, which may improve reflection characteristics of the cavity walls 108. The angled surfaces 402 may comprise reflective surfaces (e.g., metal surfaces, such as aluminum surfaces).

The light extracting material layer 110 may be chosen to be a high refractive index material that may act as a waveguide for photons emitted by the micro-LEDs. The waveguiding effect of the light extracting material layer may act to spread the angular distribution of emitted photons to thereby make the distribution of photons more uniform. As described above, a uniform distribution of emitted photons may couple to the color conversion material 112 more efficiently than may otherwise occur without the presence of the light extracting material layer 110.

The light extracting material layer 110 may be chosen to have an index of refraction that is close to that of the micro-LEDs 102. In various embodiments, the micro-LEDs may include GaN, which has an index of refraction in a range from approximately 2.4 to 2.5. As such, the light extracting material layer 110 may be chosen to have a similar index of refraction (or a wider range such as from approximately 1.5 to approximately 2.5) so that photons emitted from the micro-LEDs may be coupled to waveguide modes of the light extracting material layer 110. The material chosen for the light extracting material layer 110 may further be chosen to be transparent and to have a small extinction coefficient (i.e., to avoid absorption of photons). A variety of transparent polymer resins may be used for the light extracting material layer 110 in various embodiments.

In various additional embodiments, the light extracting material layer 110 may be a composite material having a high refractive index matrix with light extraction and scattering features. For example, the matrix may include an epoxy or UV-curable polymer and the light extraction and scattering features may include a plurality of scattering particles dispersed throughout the matrix. The scattering particles may include a material with a high refractive index, such as TiO₂, ZrO₂, or AN and the particles may be formed as nanoparticles (e.g., having a diameter of 1 nm to 1 micron). Other embodiments may include other materials and other-sized particles. Photons interacting with the nanoparticles may experience multiple scatterings, which may randomize the spatial distribution of photons. As described above, a more uniform photon distribution may lead to more efficient conversion of photons by the color conversion material 112. A variety of transparent polymer binders or resins may be chosen for the matrix in combination with high index nanoparticles to form the light extracting material layer 110.

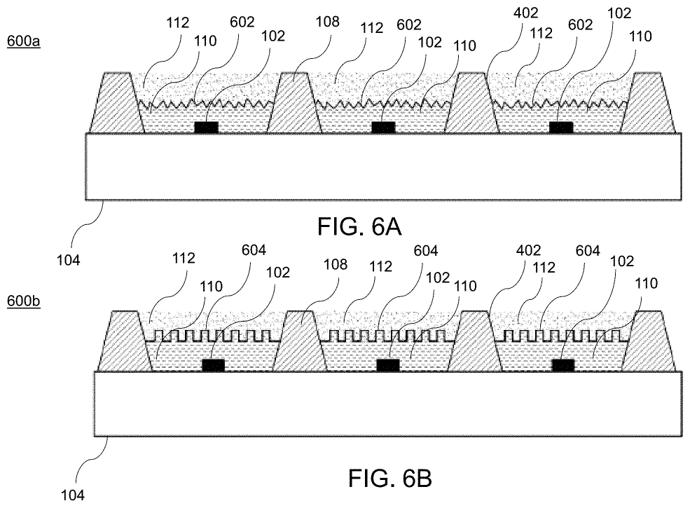

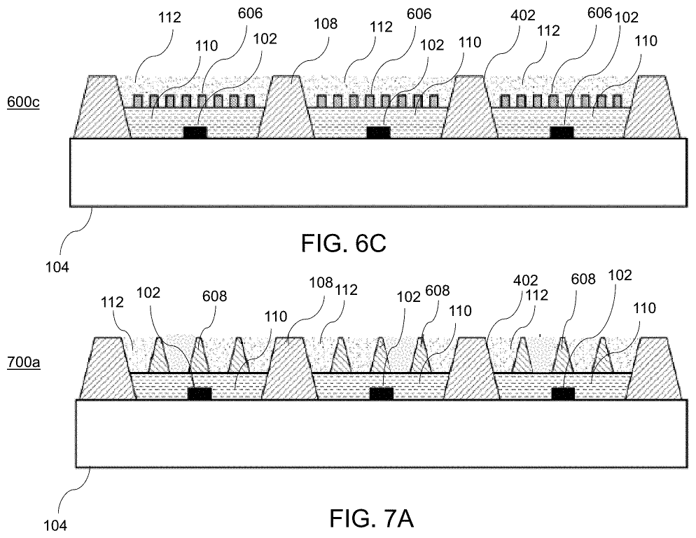

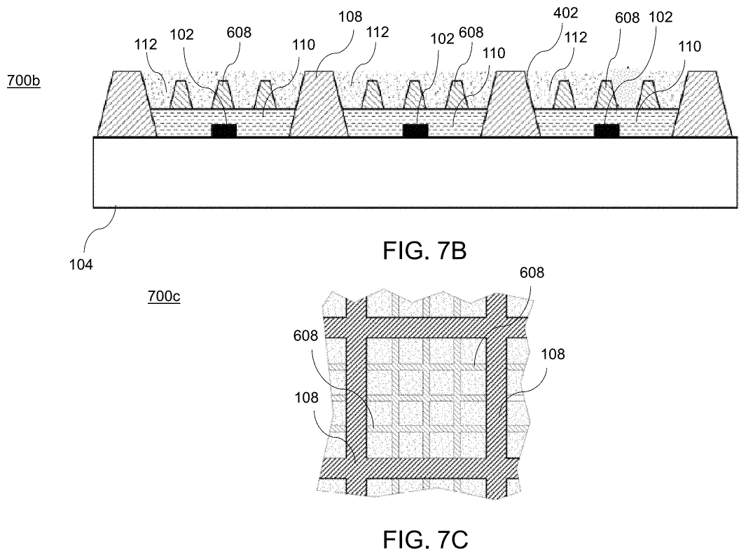

A difference of index of refraction between the light extracting material layer 110 and the color conversion material 112, however, may lead to a reduced coupling between the light extracting material layer 110 and the color conversion material 112. In this regard, a fraction of photons may be trapped in the light extracting material layer 110 due to total internal reflection that arises due to a difference in the index of refraction between the light extracting material layer 110 and the color conversion material 112. Photons that are incident on an interface between the light extracting material layer 110 and the color conversion material 112 at an angle greater than a critical angle (that depends on the index of refraction difference) may be internally reflected and may thus be trapped within the light extracting material layer 110. To address this issue, various light extraction features may be included in further embodiments to improve the coupling between the light extracting material layer 110 and the color conversion material 112, as described in greater detail with reference to FIGS. 6A to 7C, below.

FIG. 6A is a vertical cross-sectional view of a further array 600a of light emitting devices including a light extracting material layer 110 and light extracting features 602, according to various embodiments. The array 600 of light emitting devices may include a plurality of micro-LEDs 102 that are formed within a plurality of cavities that are bounded by cavity walls 108. The micro-LEDs 102 may be coupled to a substrate 104, which may include electrical circuitry that is configured to control the micro-LEDs 102. Each cavity may include a color conversion material 112 and light extracting material layer 110. The cavity walls 108 may include angled surfaces 402, which may improve reflection characteristics of the cavity walls 108. The light extracting material layer 110 may be chosen to be a high refractive index material that may act as a waveguide for photons emitted by the micro-LEDs, as described above.

The light extracting features 602 may be formed by roughening a top surface of the light extracting material layer 110 prior to deposition of the color conversion material 112. Thus, the interface between the light extracting material layer 110 and the color conversion material 112 is roughened to includes features 602 comprising peaks and valleys in the interface. Photons incident on the light extracting features 602 may be more likely to be transmitted from the light extracting material layer 110 to the color conversion material 112. In this regard, the criterion for total internal reflection (i.e., photons incident at an angle larger than a critical angle relative to a direction perpendicular to the interface) may be less likely to be satisfied because the light extracting features 602 present a plurality of surfaces having a range of angles relative to a direction perpendicular to the interface between the light extracting material layer 110 and the color conversion material 112. As such, the presence of the light extracting features 602 may increase transmission of photons from the light extracting material layer 110 to the color conversion material 112. In this way, optical extraction efficiency may be increased.

FIGS. 6B and 6C are vertical cross-sectional views of further arrays (600b, 600c) of light emitting devices each including a light extracting material layer 110 and light extracting features (604, 606), according to various embodiments. The arrays (600b, 600c) of light emitting devices may each include a plurality of micro-LEDs 102 that are formed within a plurality of cavities that are bounded by cavity walls 108. The micro-LEDs 102 may be coupled to a substrate 104, which may include electrical circuitry that is configured to control the micro-LEDs 102. Each cavity may include a color conversion material 112 and a light extracting material layer 110. The cavity walls 108 may include angled surfaces 402, which may improve reflection characteristics of the cavity walls 108. The light extracting material layer 110 may be chosen to be a high refractive index material that may act as a waveguide for photons emitted by the micro-LEDs, as described above.

The light extracting features (604, 606) in arrays (600b, 600c) may include corrugated structures formed on the light extracting material layer 110. For example, the light extracting features (604, 606) may each form a nano-scale photonic crystal. The light extracting features 604 of the array 600b may be formed by patterning the surface of the light extracting material layer 110 to form a periodic array of nano-scale features. Various patterning techniques, such as nanoimprint lithography, may be used to generate the light extracting features 604 of the array 600b. The light extracting features 604 may comprise a periodic (i.e., regular) array of battlement shaped protrusions and recesses etched or stamped into the top surface of the light extracting material layer 110.

The light extracting features 606 of the array 600c may be formed by depositing a second material over the light extracting material layer 110 and patterning the second material to form the light extracting features 606. The second material may be chosen to have a different index of refraction from that of the light extracting material layer 110. For example, the second material may be chosen to have an index of refraction that is intermediate between that of the light extracting material layer 110 and the color conversion material 112. The presence of the light extracting features 606 may thereby act to reduce the discontinuity in the index of refraction between the light extracting material layer 110 and the color conversion material 112. Various patterning techniques, such as nanoimprint lithography, may be used to generate the light extracting features 606 of the array 600c. The light extracting features 606 may comprise a periodic (i.e., regular) array of battlement shaped protrusions and recesses formed over the top surface of the light extracting material layer 110.

The periodic variations in the index of refraction caused by the spatial variation of the light extracting features (604, 606) may alter the coupling of optical modes in the light extracting material layer 110 and optical modes in the color conversion material 112. In this way, the presence of the light extracting features (604, 606) may increase transmission of photons from the light extracting material layer 110 to the color conversion material 112 and may thereby increase optical extraction efficiency.

Various additional geometric shapes may be used in forming light extracting features in additional embodiments, as described in greater detail with reference to FIGS. 7A to 7C, below. FIGS. 7A to 7C show various views of arrays of light emitting devices in which each subpixel has been divided into a plurality of sub-cells, according to various embodiments. In this regard, FIG. 7A is vertical cross-sectional view of a first array 700a of light emitting devices, FIG. 7B is a vertical cross-sectional view of a second array 700b of light emitting devices, and FIG. 7C is a top view of a third array 700c of light emitting devices. In each of the arrays (700a, 700b, 700c), a plurality of partition structures 608 may be formed over a light extracting material layer 110. However, unlike the cavity walls 108 which extend through the light extracting material layer 110 and may form the boundaries of each subpixel of a display device, the partition structures 608 are located over the top surface of the light extracting material layer 110 in each subpixel and may be surrounded by the cavity walls 108. A subpixel may comprise a single color (e.g., red, green or blue) emitting region of a light emitting device, while a pixel may comprise several subpixels (e.g., three or four pixels, such as a red subpixel, a green subpixel and a blue subpixel). The partition structures 608 may comprise a metal (e.g., aluminum), metal oxide (e.g., aluminum oxide) or polymer material.

As shown, in the first array 700a, the partition structures 608 may have a height that approximately equal to that of the surrounding color conversion material 112, while in the second array 700b, the partition structures 608 may have a height that is less than the color conversion material 112. As shown in FIG. 7C, the partition structures 608 may be formed as a periodic grid having a first plurality of parallel structures extending along a first direction (e.g., shown left to right in FIG. 7C) and a second plurality of parallel structures extending along a second direction (e.g., shown top to bottom in FIG. 7C). Thus, each subpixel may be divided into four or more regions (e.g., sub-cells), such as 9 to 12 regions, for example.

The partition structures 608 may be chosen to have an index of refraction that is different from that of the light extracting material layer 110 and of the color conversion material 112. For example, the partition structures 608 may be chosen to have an index of refraction that is less than that of the light extracting material layer 110 and greater than that of the color conversion material 112. In this way, the partition structures 608 may act as waveguides that couple photons out of the light extracting material layer 110 and into the color conversion material 112.

Each of the partition structures 608 thereby divides the color conversion material 112 into a plurality of separate regions. In this embodiment, the partition structure 608 have a tapered shape and therefore divide the color conversion material 112 into a plurality of tapered regions, which each may act as a thin and long tapered light source. Such a thin, long, tapered light source may have increased coupling efficiency relative to a corresponding thick and short light source. This phenomenon may be enhanced by choosing the refractive index of the material surrounding each partition structure 608 (i.e., the color conversion material 112) to be lower than that of the partition structures 608, as described above.

In various embodiments, the micro-LEDs 102 may comprise organic light emitting diodes (OLEDs). Such OLEDs may have a very thin active layer and, as such, each OLED may act as essentially a two-dimensional structure (i.e., in a plane parallel to a top surface of the substrate 104 in FIGS. 7A and 7B). The efficiency of such OLEDs may be almost constant, independent of a size of an emission area (e.g., a size of the top emitting surface in FIG. 3). However, in a display system where micro-LEDs 102 and color conversion materials 112 are combined, the light extraction efficiency may depend on a shape of the light source due to the device thickness. In various embodiments, a thickness of each micro-LED 102 may be approximately a few micrometers (e.g., less than 20 microns), and the light extraction efficiency may vary depending on emission angle (e.g., see FIG. 3), the type of material used for the partition structures 608, and refractive index of the material (e.g., the color conversion material 112) surrounding the partition structures 608.

As mentioned above, the light extraction efficiency of a thin and long tapered light source (e.g., tapered regions of color conversion material 112 separated by partition structures 608) may be greater than a thick and short light source (e.g., the color conversion material 112 without partition structures 608). As shown in FIGS. 7A to 7C, for example, a light source with a thin tapered color conversion material 112 may be formed by dividing each pixel into several sub-cells. As shown in FIG. 7C, a single subpixel may be divided into 12 sub-cells. Other embodiments may include various other divisions of subpixels into sub-cells. Further, each sub-cell may be bounded by structures having various cross-sectional shapes, such as circles, squares, polygons, or other irregular shapes, in other embodiments. Other embodiments may include sub-cells having many different shapes (e.g., circles, squares, polygons, or other irregular shapes).

By creating multiple sub-cells in a given subpixel size, a plurality of narrow and long light sources are created. The light extraction efficiency may depend not only on the shape but also on the refractive index of the encapsulation material surrounding the sidewall of each of the partition structures 608. Thus, as described above, the light extraction efficiency may be increased by configuring the color conversion material 112 to have a lower index of refraction than the partition structures 608 and the light extracting material layer 110.

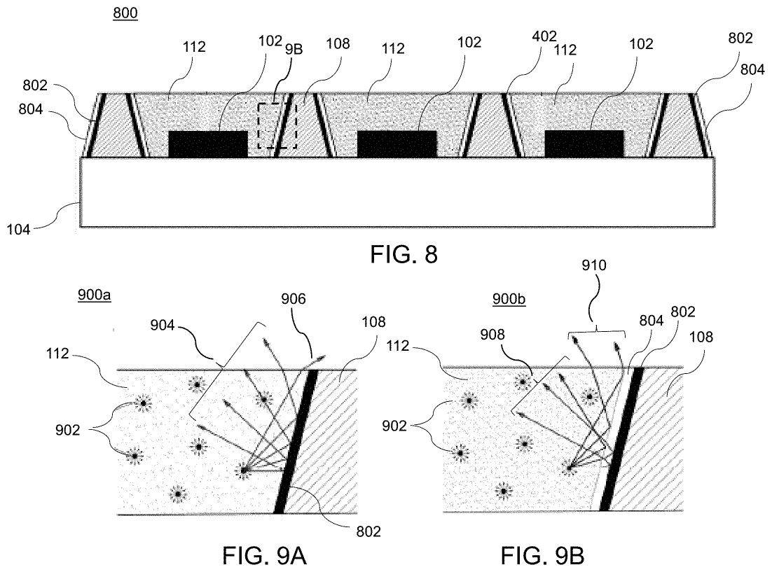

FIG. 8 is a vertical cross-sectional view of a further array 800 of light emitting devices in which cavity walls 108 may be configured to include reflecting materials, according to various embodiments. The array 800 of light emitting devices may include a plurality of micro-LEDs 102 that are formed within a plurality of cavities that are bounded by the cavity walls 108. The micro-LEDs 102 may be coupled to a substrate 104, which may include electrical circuitry that is configured to control the micro-LEDs 102. Each cavity may include a color conversion material 112.

As in other embodiments, described above, the cavity walls 108 may include angled surfaces 402, which may improve reflection characteristics of the cavity walls 108. Further, the cavity walls 108 may include reflecting materials. For example, the cavity walls 108 may be covered by a metallic material 802 in some embodiments. In further embodiments, as shown in FIG. 8, a transparent material 804 may be formed over the metallic material 802. The reflecting materials may increase light extraction efficiency by reflecting photons back into the color conversion material 112.

FIG. 9A is a vertical cross-sectional view of reflection pattern of photons hitting a reflecting cavity wall 108 having a metallic material (i.e., metal reflector) 802 on its surface. FIG. 9B is a vertical cross-sectional view of reflection pattern of photons hitting a reflecting cavity wall 108 having a transparent material 804 formed over a metallic material (i.e., metal reflector) 802 in region 9B of FIG. 8, according to various embodiments. The color conversion material 112 may include a plurality of discrete color conversion objects 902 (e.g., quantum dots). Each of the plurality of discrete color conversion objects 902 may radiate converted photons in all directions. Some of the radiated photons 904 may hit the metallic material 802 and may be reflected back into the color conversion material 112. Other photons 906 may be emitted by the discrete color conversion objects 902 at such an angle that the photons 906 do not hit the metallic material 802 and thereby exit the color conversion material 112 without reflection.

Metal reflectors (e.g., metallic material 802) may be used in lighting applications and optical components. Metallic materials 802 generally have a reflectivity is considerably high, with the reflectivity exceeding 85% for aluminum reflectors and exceeding 90% for silver. However, photons propagating within materials having a relatively high refractive index (e.g., the color conversion material 112) may not be easily extracted, and may experience multiple reflections before exiting the material. With each reflection, there is a certain probability that the photon may be absorbed, since the metallic material 802 is not perfectly reflecting. In this way, the reflectance is exponentially reduced with each reflection. As such, the effective reflectivity of a metallic material 802 that coats a cavity wall 108, as shown in FIG. 9A, may be significantly lower than the reflectivity of the metallic material 802 in air. As described in greater detail with reference to FIG. 9B, the reflectivity may be increased by covering the metallic material 802 with a transparent material (e.g., DBR, etc.) that causes a fraction of incident photons to undergo total internal reflection with essentially no loss.

As shown in FIGS. 8 and 9B, the metallic material 802 may be coated with a transparent material 804. The transparent material 804 may be chosen to be a low refractive index material, a total internal reflector (TIR), an omni-directional reflector (ODR) or a DBR. Photons 908 that are incident at small angles relative to a direction perpendicular to the cavity wall 108 may be reflected by the metallic material 802. Other photons 910 that are incident a larger angles may be reflected by the transparent material 804 without interacting with the metallic material 802. In this regard, photons 910 that are incident at an angle equal to or greater than a critical angle may experience total internal reflection from the transparent material 804. These photons 910 therefore do not experience the exponential attenuation that they would otherwise experience in the absence of the transparent material 804. In this way, a fraction of reflected photons that suffer attenuation due to reflection from the metallic material 802 may be reduced. As such, the overall reflectivity of the cavity wall 108 may be increased.

The efficiency of total internal reflection may be configured to be close to 100%. Thus, even if a photon experiences multiple total internal reflections, the loss (i.e., attenuation) of photon would be negligible. The boundary conditions of an electric field associated with a photon dictates that the electric field penetrates to a certain depth within the transparent material 804. Within the transparent material 804, the electric field is an evanescent wave having exponentially decreasing amplitude with distance from the surface of the transparent material 804. To prevent absorption by the metallic material 802, the transparent material 804 may be chosen to have a thickness that is greater than the penetration depth. For example, in certain embodiments, the transparent material 804 may be chosen to have a thickness of approximately 1 micron or greater, such as 1 to 10 microns to avoid photon absorption.

As mentioned above, the transparent material 804 may be formed as a DBR. In this regard, the DBR may be formed as a plurality of layers having an alternating refractive index. By appropriate choice of the refractive indices of the alternating layers, the DBR may be constructed to have high reflectivity, and when placed on the metallic material 802, a reflecting structure may be formed that has significantly higher reflectivity than a single metal layer alone. In an example embodiment, the DBR may include alternating layers of TiO₂ and SiO₂. Further, the number of alternating layers and the individual layer thicknesses may be optimized to achieve high reflectivity at a wavelength corresponding to a central wavelength of the micro-LEDs 102. In this way, the DBR may be configured to reflect UV-radiation and/or blue light emitted by the micro-LEDs 102. As such, the DBR may increase the probability that the reflected photons will be converted to longer wavelength photons by the color conversion material 112. Various materials may be used for constructing the transparent material 804 including various dielectric materials, polymers, resins, etc., having various refractive indices.

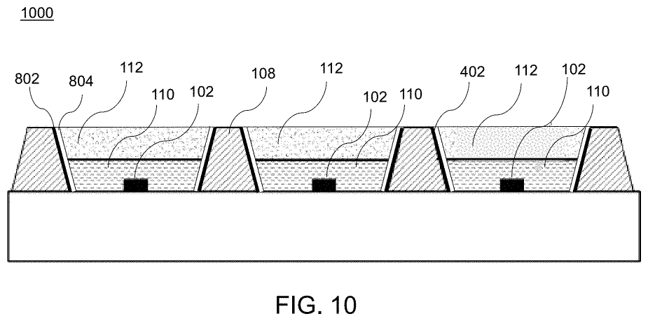

In the embodiment shown in FIG. 8, the light extracting material layer 110 may be omitted. In another embodiment shown in FIG. 10, the light extracting material layer 110 is used in combination with the transparent material 804 described above. FIG. 10 is a vertical cross-sectional view of a further array 1000 of light emitting devices which contain both the light extracting material layer 110 and the transparent material 804 located over the metallic material 802 on cavity walls 108.

The preceding description of the disclosed embodiments is provided to enable persons of ordinary skill in the art to make or use the disclosed embodiments. Various modifications to these embodiments will be readily apparent to those of ordinary skill in the art, and the generic principles defined herein may be applied to other embodiments without departing from the spirit or scope of the disclosure. Thus, the disclosure is not intended to be limited to the embodiments shown herein but is to be accorded the widest scope consistent with the following claims and the principles and novel features disclosed herein.

What is claimed is:

1. A light emitting device, comprising:
a light emitting diode configured to emit blue or ultraviolet radiation incident photons;
a color conversion material located over the light emitting diode and configured to absorb the incident photons emitted by the light emitting diode and to generate converted photons having a longer peak wavelength than a peak wavelength of the incident photons; and
at least one light extracting feature located between the light emitting diode and the color conversion material.

2. The light emitting device of claim 1, further comprising an optical cavity bounded by a cavity wall, wherein the light emitting diode is located in the optical cavity.

3. The light emitting device of claim 2, wherein the at least one light extracting feature comprises a first light extracting material layer located in the optical cavity between the light emitting diode and the color conversion material.

4. The light emitting device of claim 3, wherein:
the light emitting diode comprises a Group III— nitride active region; and
the first light extracting material layer comprises a first index of refraction that is in a range from approximately 1.5 to approximately 2.5.

5. The light emitting device of claim 3, wherein the first light extracting material layer comprises light extraction features comprising a rough interface between the first light extracting material layer and the color conversion material.

6. The light emitting device of claim 3, wherein the first light extracting material layer comprises light extraction features comprising a periodic array of nanoscale features that comprise a nanoscale photonic crystal that couples optical modes of the first light extracting material layer and optical modes of the color conversion material.

7. The light emitting device of claim 3, further comprising a second light extracting material layer comprising a corrugated height profile located over the first light extracting material layer.

8. The light emitting device of claim 7, wherein the second light extracting material layer comprises a second index of refraction that is different from a first index of refraction of the first light extracting material layer.

9. The light emitting device of claim 3, further comprising a plurality of partition structures formed over the first light extracting material layer that divide the optical cavity into a plurality of sub-cells, wherein the color conversion material is formed within the plurality of sub-cells.

10. The light emitting device of claim 9, wherein each of the plurality of partition structures comprises a tapered shape.

11. The light emitting device of claim 3, wherein the first light extracting material layer comprises a plurality of light scattering nanoparticles which are dispersed in a matrix.

12. The light emitting device of claim 11, wherein the plurality of light scattering nanoparticles comprise TiO₂, ZrO₂, or AN nanoparticles and the matrix comprises an epoxy or a UV curable polymer.

13. The light emitting device of claim 3, further comprising a reflective material formed over the cavity wall and a transparent material formed over the reflective material.

14. The light emitting device of claim 13, wherein the transparent material is configured to cause total internal reflection of photons incident at an angle greater than a critical angle relative to a direction perpendicular to a surface of the transparent material.

15. The light emitting device of claim 13, wherein:
the transparent material has a thickness that is greater than a penetration depth of an evanescent field associated with a reflecting photon; and
the reflective material comprises a metallic material formed over the cavity wall.

16. The light emitting device of claim 13, wherein the transparent material comprises a distributed Bragg reflector.

17. A light emitting device, comprising:
an optical cavity bounded by a cavity wall;
a light emitting diode located in the optical cavity and configured to emit blue or ultraviolet radiation incident photons;
a color conversion material located over the light emitting diode and configured to absorb the incident photons emitted by the light emitting diode and to generate converted photons having a longer peak wavelength than a peak wavelength of the incident photons;
a reflective material located over the cavity wall; and
a transparent material located over the reflective material.

18. The light emitting device of claim 17, wherein the transparent material is configured to cause total internal reflection of photons incident at an angle greater than a critical angle relative to a direction perpendicular to a surface of the transparent material.

19. The light emitting device of claim 17, wherein:
the transparent material has a thickness that is greater than a penetration depth of an evanescent field associated with a reflecting photon; and
the reflective material comprises a metallic material formed over the cavity wall.

20. The light emitting device of claim 17, wherein the transparent material comprises a distributed Bragg reflector.
